(19) United States
(12) Patent Application Publication
(10) Pub. No.: US 2021/0088840 A1
(43) Pub. Date: Mar. 25, 2021

(54) METHOD OF HAVING A POLARIZER BUILT IN A LCD PANEL, LCD DEVICE, AND LCD DEVICE MANUFACTURING METHOD

(71) Applicant: Wuhan China Star Optoelectronics Technology Co., Ltd., Wuhan (CN)

(72) Inventors: Chaoqun Yang, Wuhan (CN); Changchih Huang, Wuhan (CN)

(73) Assignee: Wuhan China Star Optoelectronics Technology Co., Ltd., Wuhan (CN)

(21) Appl. No.: 16/308,482

(22) PCT Filed: Sep. 22, 2018
(86) PCT No.: PCT/CN2018/107145

§ 371 Date: Dec. 10, 2018

(30) Foreign Application Priority Data
May 23, 2018 (CN) 201810502029.8

(51) Int. Cl. G02F 1/1335; G02F 1/1339; G02F 1/13357; G03F 7/00

(52) U.S. Cl. CPC G02F 1/133528; G02F 1/133516; G02F 1/1339; G02F 1/133617; G02F 2001/133354; G02F 2001/133548; G02F 2202/10; G02F 2201/50; G02F 2202/36; G03F 7/0002

(57) ABSTRACT

The present invention teaches a method of having a built-in polarizer in a LCD panel, a LCD device, and a LCD device manufacturing method. The method of having built-in polarizer in a LCD panel taught by the present invention uses a nano imprinting technique to form a wire-grid built-in polarizer. The built-in polarizer, when applied to a LCD device, is able to resolve the QDCF-based product's difficulty in controlling light's on and off and to enhance backlight utilization efficiency. The built-in polarizer has a sandwich structure where a metallic wire grid layer is sandwiched between a first inorganic protection layer and a second inorganic protection layer, preventing the metallic wire grid layer from erosion by oxidation and enhancing the operation life of the built-in polarizer.

### FIELD OF THE INVENTION

The present invention is generally related to the field of display technology and more particularly to a method of having a polarizer built in a LCD panel, a LCD device, and a LCD device manufacturing method.

### BACKGROUND OF THE INVENTION

Thin film transistor (TFT) liquid crystal display (LCD) devices are gaining fast development and widespread application. Most of existing LCD devices are back-lighted LCD devices, and include a LCD panel and a backlight module. The LCD panel includes a color filter (CF) substrate, a thin film transistor (TFT) array substrate, a liquid crystal layer disposed between the two substrates, and sealant. The LCD panel is operated by applying driving voltages across the substrates to control the alignment of the liquid crystal molecules in the liquid crystal layer, and to refract light from the backlight module to produce pictures.

Existing LCD devices achieve colorful presentation through the use of a color filter (CF) layer. A conventional CF layer is formed using color photoresist material through a series of lithographic processes. The color photoresist material is obtained by dissolving or dispersing polymer, monomer, photo initiator, and pigment in a solvent. Conventional LCD panels using such CF layer often suffer low color saturation, and their color presentation is not bright enough. On the other hand, backlight technique based on quantum dots (QDs) is already in mass production, and is able to achieve 110% NTSC gamut value, much higher than the 90%-100% NTSC level of conventional LCD devices.

QDs are not visible to naked eyes. They involve very tiny inorganic nanocrystals, mostly formed by II-VI or III-V elements into a three-dimensional nanomaterial. Due to the quantum confinement effect, the transportation of internal electrons and holes are limited, turning continuous energy band structure into discrete energy level structure. When excited by light or external energy, QDs would emit color light. The color of the light is determined by the materials and dimensions of the QDs. When the QDs are of different dimensions, the electrons and holes suffer different degrees of quantum confinement, and the discrete energy level structures are also different. For smaller particles, they absorb long-wavelength light, and larger particles absorb short-wavelength light. Usually QDs absorb short-wavelength blue light, and are excited to produce long-wavelength light. This characteristic allows QDs to change the color of light from the light source.

The advantages of QDs are as follows. Their light has a wavelength range that may cover infra-red and visible light band by controlling QDs' dimensions. Their light may also have narrow bandwidth, and high color saturation. In addition, QD material has high quantum conversion efficiency, stable material performance, simplified and flexible manufacturing, etc. Therefore, applying QDs in color filter may produce QD color filter (QDCF), which may replace conventional CF and may further enhance color gamut >90% BT.2020 (BT.2020 color gamut corresponds to 134% NTSC gamut value).

To make QDCF using QD nanomaterial, a series of solvents and ligands are required. The industry has already made some progress. However, QDs have a mechanism in producing color different from that of the existing CF's use of pigment. QDs are excited to produce light of a specific wavelength due to energy band structural change. If a LCD device has a polarizer (POL) attached to a glass substrate, then linearly polarized light may be produced as backlight pass through the polarizer. If QDs are excited by the linearly polarized light, the produced light may lose polarization or have different polarization direction, causing uncontrollability in light path and brightness, and failure to achieve light's on and off. Therefore, QDCF cannot directly replace existing CF in existing LCD devices.

### SUMMARY OF THE INVENTION

An objective of the present invention is to provide a method of having a built-in polarizer in a LCD panel that uses a nano imprinting technique to form a wire-grid built-in polarizer. The built-in polarizer, when applied to a LCD device, is able to resolve the QDCF-based product's difficulty in controlling light's on and off and to enhance backlight utilization efficiency.

Another objective of the present invention is to provide a LCD device having a wire grid built-in polarizer that is able to resolve the QDCF-based product's difficulty in controlling light's on and off and to enhance backlight utilization efficiency.

Yet another objective of the present invention is to provide a LCD device manufacturing method using a nano imprinting technique to form a wire grid built-in polarizer that is able to resolve the QDCF-based product's difficulty in controlling light's on and off and to enhance backlight utilization efficiency.

To achieve the objectives, the present invention first teaches a method of having a built-in polarizer in LCD panel, comprising

Step S1: providing a substrate, forming a first inorganic protection layer on the substrate by deposition, and sequentially forming a metallic wire grid layer and a second inorganic protection layer by deposition from bottom to top on the first inorganic protection layer;

Step S2: forming a photoresist layer by coating on the second inorganic protection layer, providing a first nano imprinting template, imprinting the photoresist layer through the first nano imprinting template, and obtaining a photoresist pattern from the photoresist layer, where the photoresist pattern has a plurality of parallel photoresist bars arranged at intervals; and

Step S3: etching the second inorganic protection layer and the metallic wire grid layer with the photoresist pattern as shading layer, obtaining a plurality of parallel first metallic lines at intervals and a plurality of parallel inorganic lines at intervals beneath the photoresist bars from the metallic wire grid layer and the second inorganic protection layer, and removing the photoresist pattern, where the metallic wire grid layer, the first inorganic protection layer to the sides of the metallic wire grid layer, and the second inorganic protection layer jointly form the built-in polarizer.

The first inorganic protection layer and the second inorganic protection layer are made of one or more of silicon oxide, silicon nitride, aluminum oxide, silicon oxynitride, and yttrium oxide; and

the metallic wire grid layer is made of at least one of aluminum, copper, silver, chromium, gold, and nickel.

Two neighboring first metallic lines in the metallic wire grid layer are separated at a distance 60-80 nm; and the metallic wire grid layer has a thickness 180-250 nm.

The present invention also teaches a LCD device comprising a LCD panel, wherein

the LCD panel comprises oppositely disposed CF substrate and array substrate, and a built-in polarizer on a side of the CF substrate facing the array substrate;

the built-in polarizer comprises a first inorganic protection layer disposed on the CF substrate, a metallic wire grid layer disposed on the first inorganic protection layer, and a second inorganic protection layer disposed on the metallic wire grid layer;

the metallic wire grid layer comprises a plurality of parallel first metallic lines at intervals; and the second inorganic protection layer comprises a plurality of inorganic lines respectively above corresponding first metallic lines.

The LCD device further comprises a backlight module disposed to a side of the array substrate away from the CF substrate;

the CF substrate comprises a first substrate, a quantum dot color filter (QDCF) disposed on a side of the first substrate adjacent to the array substrate, and an organic cap layer disposed to a side of the QDCF adjacent to the array substrate; and

the LCD panel further comprises an external polarizer disposed on a side of the array substrate away from the CF substrate, a separator layer disposed to a side of the built-in polarizer adjacent to the array substrate, and a liquid crystal layer disposed between the CF substrate and the array substrate.

The external polarizer is a metallic wire grid polarizer.

The present invention also teaches a LCD device manufacturing method, comprising steps of forming a CF substrate, forming a built-in polarizer on the CF substrate, forming an array substrate, and assembling an LCD panel, wherein

in assembling the LCD panel, the CF substrate and the array substrate are disposed oppositely; the built-in polarizer is disposed on a side of the CF substrate facing the array substrate; and

the built-in polarizer is formed according to the method as described above, whose substrate in step S1 is the CF substrate.

The LCD device manufacturing method further comprises the steps of forming a separator layer on the built-in polarizer, forming an external polarizer on the array substrate, and assembling the LCD device, wherein

the LCD device comprises the LCD panel and a backlight module; the backlight module is disposed to a side of the array substrate away from the CF substrate; and

in assembling the LCD panel, the CF substrate comprises a first substrate, a QDCF disposed on a side of the first substrate adjacent to the array substrate, and an organic cap layer disposed to a side of the QDCF adjacent to the array substrate.

The external polarizer is a metallic wire grid polarizer.

The step of forming the external polarizer is through a nano imprinting technique and comprises the steps of:

Step S10: forming a metallic film layer on the array substrate by deposition;

Step S20: forming a photoresist film layer by coating on the metallic film layer, providing a second nano imprinting template, imprinting the photoresist film layer through the second nano imprinting template, and obtaining a photoresist film pattern from the photoresist film layer; and

Step S30: etching the metallic film layer with the photoresist film pattern as shading layer, obtaining a plurality of parallel second metallic lines at intervals from the metallic film layer corresponding to the photoresist film pattern, and obtaining the external polarizer after removing the photoresist film pattern.

The advantages of the present invention are as follows. The method of having a built-in polarizer in a LCD panel taught by the present invention uses a nano imprinting technique to form a wire-grid built-in polarizer. The built-in polarizer, when applied to a LCD device, is able to resolve the QDCF-based product's difficulty in controlling light's on and off and to enhance backlight utilization efficiency. The built-in polarizer has a sandwich structure where a metallic wire grid layer is sandwiched between a first inorganic protection layer and a second inorganic protection layer, preventing the metallic wire grid layer from erosion by oxidation and enhancing the operation life of the built-in polarizer. The LCD device taught by the present invention has a wire-grid built-in polarizer. The built-in polarizer is able to resolve the QDCF-based product's difficulty in controlling light's on and off and to enhance backlight utilization efficiency. The built-in polarizer has a metallic wire grid layer sandwiched between a first inorganic protection layer and a second inorganic protection layer, preventing the metallic wire grid layer from erosion by oxidation and enhancing the operation life of the built-in polarizer. The LCD device manufacturing method taught by the present invention forms a wire-grid built-in polarizer by a nano imprinting technique after forming an organic cap layer and before forming a separator layer. The built-in polarizer is able to resolve the QDCF-based product's difficulty in controlling light's on and off and to enhance backlight utilization efficiency. The built-in polarizer has a metallic wire grid layer sandwiched between a first inorganic protection layer and a second inorganic protection layer, preventing the metallic wire grid layer from erosion by oxidation and enhancing the operation life of the built-in polarizer.

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 shows light passing through a conventional polarizer and a wire grid polarizer.

FIG. 2 is a flow diagram showing a method having a built-in polarizer in a LCD panel.

FIG. 3 is a schematic diagram showing a step S1 of the method of FIG. 2.

FIGS. 4 to 6 are schematic diagrams showing a step S2 of the method of FIG. 2.

FIGS. 7 and 8 are schematic diagrams showing a step S3 of the method of FIG. 2.

FIG. 9 is a structural schematic diagram showing a LCD device according to an embodiment of the present invention.

FIG. 10 is a schematic diagram showing a step S10 of forming an external polarizer in a LCD device manufacturing method according to an embodiment of the present invention.

FIGS. 11 to 13 are schematic diagrams showing a step S20 of forming an external polarizer in a LCD device manufacturing method according to an embodiment of the present invention.

FIGS. 14 and 15 are schematic diagrams showing a step S30 of forming an external polarizer in a LCD device manufacturing method according to an embodiment of the present invention.

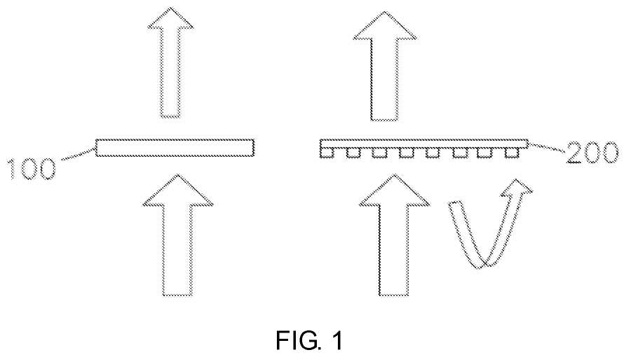

### DETAILED DESCRIPTION OF PREFERRED EMBODIMENTS

The following descriptions for the respective embodiments are specific embodiments capable of being implemented for illustrations of the present invention with referring to appended figures.

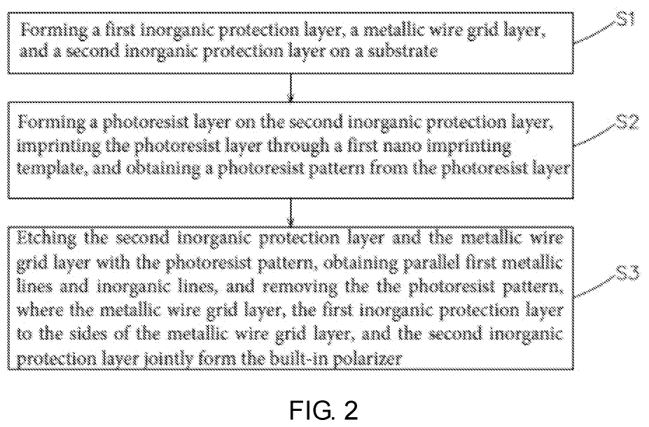

As shown in FIG. 2, the present invention teaches a method of having a built-in polarizer 30 including the following steps:

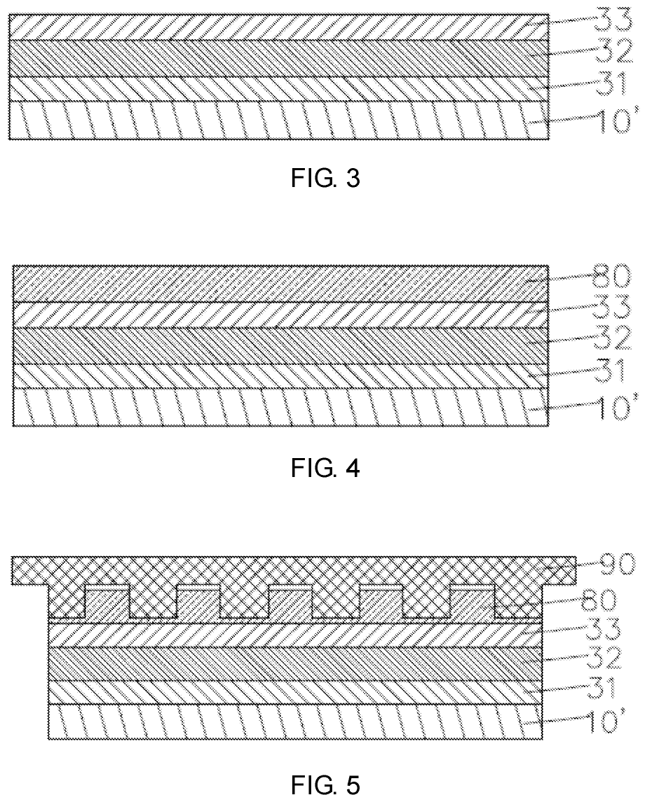

Step S1: as shown in FIG. 3, providing a substrate 10′, forming a first inorganic protection layer 31 on the substrate 10′ by deposition, and sequentially forming a metallic wire grid layer 32 and a second inorganic protection layer 33 by deposition from bottom to top on the first inorganic protection layer 31;

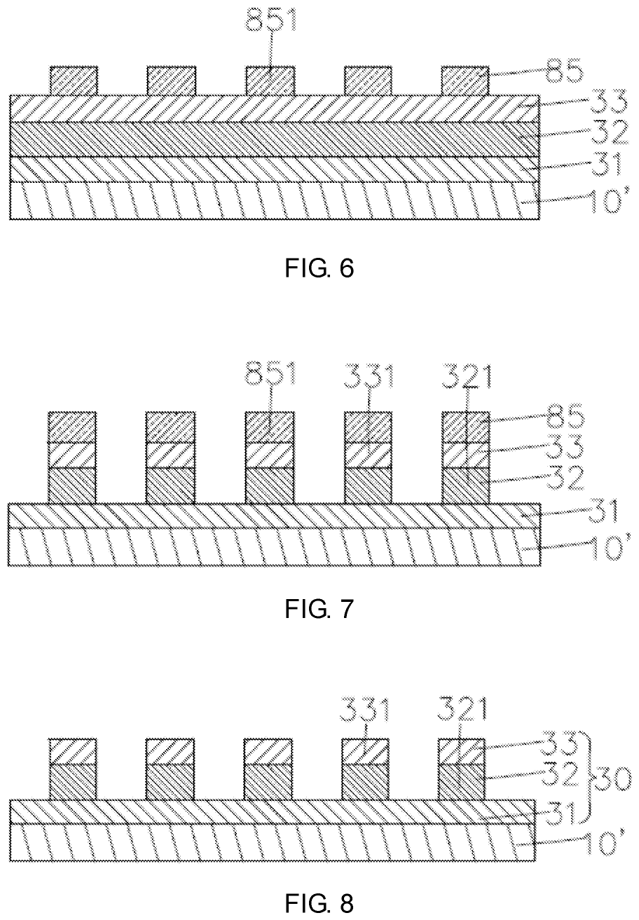

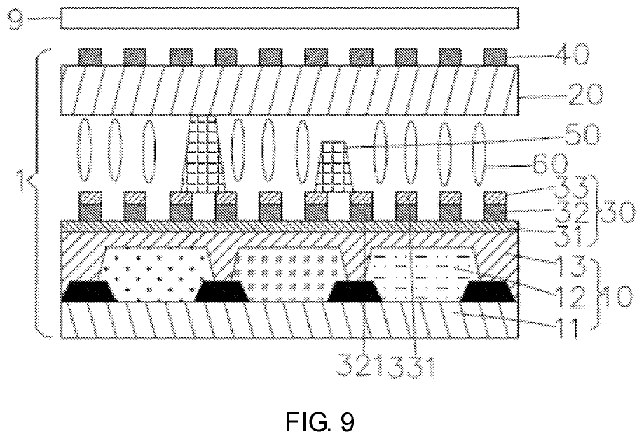

Step S2: as shown in FIGS. 4 to 6, forming a photoresist layer 80 by coating on the second inorganic protection layer 33, providing a first nano imprinting template 90, imprinting the photoresist layer 80 through the first nano imprinting template 90, and obtaining a photoresist pattern 85 from the photoresist layer 80, where the photoresist pattern 85 has multiple parallel photoresist bars 851 arranged at intervals; and

Step S3: as shown in FIGS. 7 and 8, etching the second inorganic protection layer 33 and the metallic wire grid layer 32 with the photoresist pattern 85 as shading layer, obtaining multiple parallel first metallic lines 321 at intervals and multiple parallel inorganic lines 331 at intervals beneath the photoresist bars 851 from the metallic wire grid layer 32 and the second inorganic protection layer 33, removing the photoresist pattern 85, where the metallic wire grid layer 32, the first inorganic protection layer 31 to the sides of the metallic wire grid layer 32, and the second inorganic protection layer 33 jointly form a built-in polarizer 30.

Specifically, the first inorganic protection layer 31 and the second inorganic protection layer 33 are made of one or more of silicon oxide, silicon nitride, aluminum oxide, silicon oxynitride, and yttrium oxide. Furthermore, in the present embodiment, the first inorganic protection layer 31 is made of silicon oxide, and the second inorganic protection layer 33 is made of silicon nitride.

Specifically, the metallic wire grid layer 32 is made of at least one of aluminum, copper, silver, chromium, gold, and nickel. Furthermore, in the present embodiment, the metallic wire grid layer 32 is made of aluminum.

Specifically, two neighboring first metallic lines 321 of the metallic wire grid layer 32 are separated at a distance 60-80 nm. The metallic wire grid layer 32 has a thickness 180-250 nm. That is, a region between two neighboring first metallic lines 321 of the metallic wire grid layer 32 has a depth 180-250 nm.

The method of having built-in polarizer in a LCD panel taught by the present invention uses a nano imprinting technique to form a wire-grid built-in polarizer 30. The built-in polarizer 30, when applied to a LCD device, is able to resolve the QDCF-based product's difficulty in controlling light's on and off and to enhance backlight utilization efficiency. The built-in polarizer 30 has a sandwich structure where a metallic wire grid layer 32 is sandwiched between a first inorganic protection layer 31 and a second inorganic protection layer 33, preventing the metallic wire grid layer 32 from erosion by oxidation and enhancing the operation life of the built-in polarizer 30.

As shown in FIG. 0, based on the above-described method of having a built-in polarizer in a LCD panel, the present invention also teaches a LCD device, including a LCD panel 1 and a backlight module 9.

Specifically, the LCD panel 1 includes oppositely disposed CF substrate 10 and array substrate 20, a built-in polarizer 30 on a side of the CF substrate 10 facing the array substrate 20, an external polarizer 40 disposed on a side of the array substrate 20 away from the CF substrate 10, a separator layer 50 disposed to a side of the built-in polarizer 30 adjacent to the array substrate 20, and a liquid crystal layer 60 disposed between the CF substrate 10 and the array substrate 20.

Specifically, the backlight module 9 is disposed to a side of the array substrate 20 away from the CF substrate 10.

Specifically, the built-in polarizer 30 is formed using the above described method of having a built-in polarizer in a LCD panel, and includes a first inorganic protection layer 31 on the CF substrate 10, a metallic wire grid layer 32 on the first inorganic protection layer 31, and a second inorganic protection layer 33 on the metallic wire grid layer 32.

The metallic wire grid layer 32 has a wire grid pattern, and includes multiple parallel first metallic lines 321 at intervals. The second inorganic protection layer 33 has a wire grid pattern identical to that of the metallic wire grid layer 32. The second inorganic protection layer 33 includes multiple inorganic lines 331 respectively above corresponding first metallic lines 321.

Specifically, the CF substrate 10 includes a first substrate 11, a QDCF 12 disposed on a side of the first substrate 11 adjacent to the array substrate 20, and an organic cap layer 13 disposed to a side of the QDCF 12 adjacent to the array substrate 20.

Specifically, to further enhance light transmittance and backlight utilization of the LCD device, the external polarizer 40 is also a wire grid polarizer and, more specifically, a metallic wire grid polarizer.

Specifically, the first inorganic protection layer 31 and the second inorganic protection layer 33 are made of one or more of silicon oxide, silicon nitride, aluminum oxide, silicon oxynitride, and yttrium oxide. Furthermore, in the present embodiment, the first inorganic protection layer 31 is made of silicon oxide, and the second inorganic protection layer 33 is made of silicon nitride.

Specifically, the metallic wire grid layer 32 is made of at least one of aluminum, copper, silver, chromium, gold, and nickel. Furthermore, in the present embodiment, the metallic wire grid layer 32 is made of aluminum.

Specifically, two neighboring first metallic lines 321 in the metallic wire grid layer 32 are separated at a distance 60-80 nm. The metallic wire grid layer 32 has a thickness 180-250 nm.

The LCD device taught by the present invention has a wire-grid built-in polarizer 30. The built-in polarizer 30 is able to resolve the QDCF-based product's difficulty in controlling light's on and off and to enhance backlight utilization efficiency. The built-in polarizer 30 has a metallic wire grid layer 32 sandwiched between a first inorganic protection layer 31 and a second inorganic protection layer 33, preventing the metallic wire grid layer 32 from erosion by oxidation and enhancing the operation life of the built-in polarizer 30.

The present invention also teaches a LCD device manufacturing method, including steps of forming a CF substrate 10, forming a built-in polarizer 30 on the CF substrate 10, forming an array substrate 20, forming a separator layer 50 on the built-in polarizer 30, forming an external polarizer 40 on the array substrate 20, assembling a LCD panel 1, and assembling the LCD device.

Specifically, in assembling the LCD panel 1, the CF substrate 10 and the array substrate 20 are disposed oppositely. The built-in polarizer 30 is disposed on a side of the CF substrate 10 facing the array substrate 20.

Specifically, the steps for forming the built-in polarizer 30 are identical to those in the above described method of having a built-in polarizer in a LCD panel, except that the substrate 10′ in step S1 is the CF substrate 10, and the first inorganic protection layer 31 is deposited on the CF substrate 10. The other details are omitted.

Specifically, the LCD device includes the LCD panel 1 and a backlight module 9. The backlight module 9 is disposed to a side of the array substrate 20 away from the CF substrate 10.

Specifically, in assembling the LCD panel 1, the CF substrate 10 includes a first substrate 11, a QDCF 12 disposed on a side of the first substrate 11 adjacent to the array substrate 20, and an organic cap layer 13 disposed to a side of the QDCF 12 adjacent to the array substrate 20.

Specifically, the external polarizer 40 is a metallic wire grid polarizer.

Furthermore, the external polarizer 40 is formed using nano imprinting technique and specifically by the following steps:

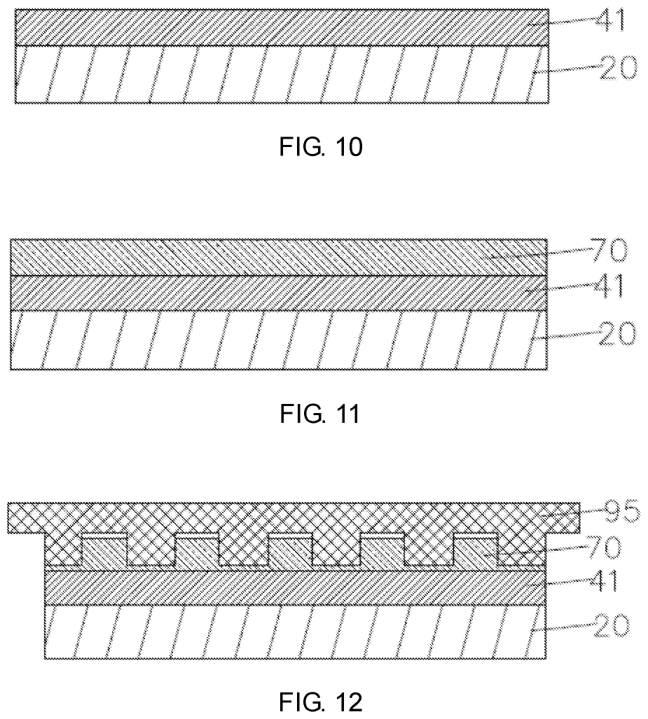

Step S10: as shown in FIG. 10, forming a metallic film layer 41 on the array substrate 20 by deposition;

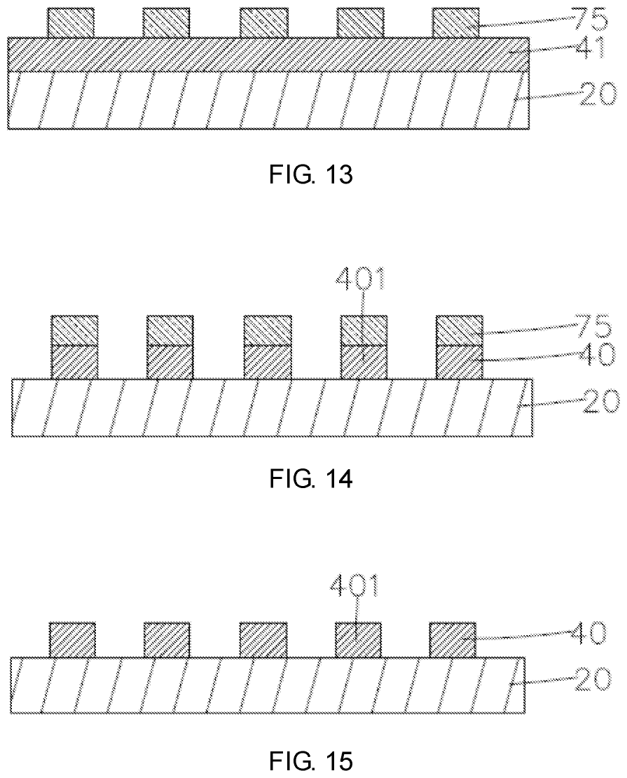

Step S20: as shown in FIGS. 11 to 13, forming a photoresist film layer 70 by coating on the metallic film layer 41, providing a second nano imprinting template 95, imprinting the photoresist film layer 70 through the second nano imprinting template 95, and obtaining a photoresist film pattern 75 from the photoresist film layer 70; and

Step S30: as shown in FIGS. 14 and 15, etching the metallic film layer 41 with the photoresist film pattern 75 as shading layer, obtaining multiple parallel second metallic lines 401 at intervals from the metallic film layer 41 corresponding to the photoresist film pattern 75, and obtaining the external polarizer 40 after removing the photoresist film pattern 75.

The LCD device manufacturing method taught by the present invention forms a wire-grid built-in polarizer 30 by a nano imprinting technique after forming an organic cap layer 13 and before forming a separator layer 50. The built-in polarizer 30 is able to resolve the QDCF-based product's difficulty in controlling light's on and off and to enhance backlight utilization efficiency. The built-in polarizer 30 has a metallic wire grid layer 32 sandwiched between a first inorganic protection layer 31 and a second inorganic protection layer 33, preventing the metallic wire grid layer 32 from erosion by oxidation and enhancing the operation life of the built-in polarizer 30.

As described above, the method of having a built-in polarizer in a LCD panel taught by the present invention uses a nano imprinting technique to form a wire-grid built-in polarizer. The built-in polarizer, when applied to a LCD device, is able to resolve the QDCF-based product's difficulty in controlling light's on and off and to enhance backlight utilization efficiency. The built-in polarizer has a sandwich structure where a metallic wire grid layer is sandwiched between a first inorganic protection layer and a second inorganic protection layer, preventing the metallic wire grid layer from erosion by oxidation and enhancing the operation life of the built-in polarizer. The LCD device taught by the present invention has a wire-grid built-in polarizer. The built-in polarizer is able to resolve the QDCF-based product's difficulty in controlling light's on and off and to enhance backlight utilization efficiency. The built-in polarizer has a metallic wire grid layer sandwiched between a first inorganic protection layer and a second inorganic protection layer, preventing the metallic wire grid layer from erosion by oxidation and enhancing the operation life of the built-in polarizer. The LCD device manufacturing method taught by the present invention forms a wire-grid built-in polarizer by a nano imprinting technique after forming an organic cap layer and before forming a separator layer. The built-in polarizer is able to resolve the QDCF-based product's difficulty in controlling light's on and off and to enhance backlight utilization efficiency. The built-in polarizer has a metallic wire grid layer sandwiched between a first inorganic protection layer and a second inorganic protection layer, preventing the metallic wire grid layer from erosion by oxidation and enhancing the operation life of the built-in polarizer.

Above are embodiments of the present invention, which does not limit the scope of the present invention. Any equivalent amendments within the spirit and principles of the embodiment described above should be covered by the protected scope of the invention.

What is claimed is:

1. A method having a built-in polarizer in a liquid crystal display (LCD) panel, comprising
Step S1: providing a substrate, forming a first inorganic protection layer on the substrate by deposition, and sequentially forming a metallic wire grid layer and a second inorganic protection layer by deposition from bottom to top on the first inorganic protection layer;
Step S2: forming a photoresist layer by coating on the second inorganic protection layer, providing a first nano imprinting template, imprinting the photoresist layer through the first nano imprinting template, and obtaining a photoresist pattern from the photoresist layer, where the photoresist pattern has a plurality of parallel photoresist bars arranged at intervals; and
Step S3: etching the second inorganic protection layer and the metallic wire grid layer with the photoresist pattern as shading layer, obtaining a plurality of parallel first metallic lines at intervals and a plurality of parallel inorganic lines at intervals beneath the photoresist bars from the metallic wire grid layer and the second inorganic protection layer, and removing the photoresist pattern, where the metallic wire grid layer, the first inorganic protection layer to the sides of the metallic wire grid layer, and the second inorganic protection layer jointly form the built-in polarizer.

2. The method of having a built-in polarizer in a LCD panel according to claim 1, wherein the first inorganic protection layer and the second inorganic protection layer are made of one or more of silicon oxide, silicon nitride, aluminum oxide, silicon oxynitride, and yttrium oxide; and
the metallic wire grid layer is made of at least one of aluminum, copper, silver, chromium, gold, and nickel.

3. The method of having a built-in polarizer in a LCD panel according to claim 1, wherein two neighboring first metallic lines in the metallic wire grid layer are separated at a distance 60-80 nm; and the metallic wire grid layer has a thickness 180-250 nm.

4. A LCD device comprising a LCD panel, wherein
the LCD panel comprises oppositely disposed CF substrate and array substrate, and a built-in polarizer on a side of the CF substrate facing the array substrate;
the built-in polarizer comprises a first inorganic protection layer disposed on the CF substrate, a metallic wire grid layer disposed on the first inorganic protection layer, and a second inorganic protection layer disposed on the metallic wire grid layer;
the metallic wire grid layer comprises a plurality of parallel first metallic lines at intervals; and the second inorganic protection layer comprises a plurality of inorganic lines respectively above corresponding first metallic lines.

5. The LCD device according to claim 4, further comprising a backlight module disposed to a side of the array substrate away from the CF substrate;
the CF substrate comprises a first substrate, a quantum dot color filter (QDCF) disposed on a side of the first substrate adjacent to the array substrate, and an organic cap layer disposed to a side of the QDCF adjacent to the array substrate; and
the LCD panel further comprises an external polarizer disposed on a side of the array substrate away from the CF substrate, a separator layer disposed to a side of the built-in polarizer adjacent to the array substrate, and a liquid crystal layer disposed between the CF substrate and the array substrate.

6. The LCD device according to claim 5, wherein the external polarizer is a metallic wire grid polarizer.

7. A LCD device manufacturing method, comprising steps of forming a CF substrate, forming a built-in polarizer on the CF substrate, forming an array substrate, and assembling an LCD panel, wherein
in assembling the LCD panel, the CF substrate and the array substrate are disposed oppositely; the built-in polarizer is disposed on a side of the CF substrate facing the array substrate; and
the built-in polarizer is formed according to the method as claimed in claim 1 whose substrate in step S1 is the CF substrate.

8. The LCD device manufacturing method according to claim 7, further comprising the steps of forming a separator layer on the built-in polarizer, forming an external polarizer on the array substrate, and assembling the LCD device, wherein
the LCD device comprises the LCD panel and a backlight module; the backlight module is disposed to a side of the array substrate away from the CF substrate; and
in assembling the LCD panel, the CF substrate comprises a first substrate, a QDCF disposed on a side of the first substrate adjacent to the array substrate, and an organic cap layer disposed to a side of the QDCF adjacent to the array substrate.

9. The LCD device according to claim 8, wherein the external polarizer is a metallic wire grid polarizer.

10. The LCD device manufacturing method according to claim 9, wherein the step of forming the external polarizer is through a nano imprinting technique and comprises the steps of:
Step S10: forming a metallic film layer on the array substrate by deposition;
Step S20: forming a photoresist film layer by coating on the metallic film layer, providing a second nano imprinting template, imprinting the photoresist film layer through the second nano imprinting template, and obtaining a photoresist film pattern from the photoresist film layer; and
Step S30: etching the metallic film layer with the photoresist film pattern as shading layer, obtaining a plurality of parallel second metallic lines at intervals from the metallic film layer corresponding to the photoresist film pattern, and obtaining the external polarizer after removing the photoresist film pattern.
